(19) United States
(12) Patent Application Publication
(10) Pub. No.: US 2025/0221095 A1
(43) Pub. Date: Jul. 3, 2025

(54) LIGHT-EMITTING ELEMENT

(71) Applicant: LG Display Co., Ltd., Seoul (KR)

(72) Inventors: IL-SOO KIM, Goyang-si (KR); YONGSEOK KWAK, Paju-si (KR); MYUNGSOO HAN, Goyang-si (KR); HYOWON KWON, Paju-si (KR)

(73) Assignee: LG Display Co., Ltd., Seoul (KR)

(21) Appl. No.: 18/912,178

(22) Filed: Oct. 10, 2024

(30) Foreign Application Priority Data
Dec. 28, 2023 (KR) 10-2023-0195579

(51) Int. Cl. H01L 33/08; H01L 25/075; H01L 25/16; H01L 33/20

(52) U.S. Cl. CPC H10H 20/813; H10H 20/819; H01L 25/0753; H01L 25/167

(57) ABSTRACT

Discussed are a light-emitting element and a display device including the light-emitting element. The light-emitting element in one example includes a first semiconductor layer, a first light-emitting layer disposed on the first semiconductor layer, a tunnel layer disposed on the first light-emitting layer, a second light-emitting layer disposed on the tunnel layer and configured to emit light with a wavelength different from a wavelength of light emitted from the first light-emitting layer, and a second semiconductor layer disposed on the second light-emitting layer. The first light-emitting layer includes a plurality of first sub-light-emitting layers configured to emit light with different wavelengths. The second light-emitting layer includes a plurality of second sub-light-emitting layers configured to emit light with different wavelengths.

### CROSS-REFERENCE TO RELATED APPLICATIONS

This application claims priority to Korean Patent Application No. 10-2023-0195579, filed on Dec. 28, 2023, in the Korean Intellectual Property Office, the entire contents of which is hereby expressly incorporated by reference into the present application.

### BACKGROUND

### Field

The present disclosure relates to a light emitting element, and more particularly, to a light emitting diode (LED) and a display device including the LED.

### Discussion of the Related Art

As display devices which are used for a monitor of a computer, a television, a cellular phone, or the like, there are an organic light emitting display (OLED) device which is a self-emitting device, a liquid crystal display (LCD) device which requires a separate light source, and the like.

An applicable range of the display device is diversified to personal digital assistants as well as monitors of computers and televisions and a display device with a large display area and a reduced volume and weight is being studied.

Further, recently, a display device including a light emitting diode (LED) is attracting attention as a next generation display device. Since the LED is formed of an inorganic material, rather than an organic material, reliability is excellent so that a lifespan thereof is longer than that of the liquid crystal display device or the organic light emitting display device. Further, the LED has a fast lighting speed, excellent luminous efficiency, and a strong impact resistance so that a stability is excellent and an image having a high luminance can be displayed.

### SUMMARY OF THE DISCLOSURE

An object to be achieved by the embodiment of the present disclosure is to provide a light-emitting element with improved luminous efficiency.

Another object to be achieved by the embodiment of the present disclosure is to provide a light-emitting element with high brightness.

Still another object to be achieved by the embodiment of the present disclosure is to provide a light-emitting element with an improved color reproduction range.

Objects of the present disclosure are not limited to the above-mentioned objects, and other objects not mentioned above, can be clearly understood by those skilled in the art from the following descriptions.

According to an aspect of the present disclosure, there is provided a light emitting diode. The light-emitting element comprises a first semiconductor layer, a first light-emitting layer disposed on the first semiconductor layer, a tunnel layer disposed on the first light-emitting layer, a second light-emitting layer disposed on the tunnel layer and configured to emit light with a wavelength different from a wavelength of light emitted from the first light-emitting layer, and a second semiconductor layer disposed on the second light-emitting layer, wherein the first light-emitting layer comprises a plurality of first sub-light-emitting layers configured to emit light with different wavelengths, and the second light-emitting layer comprises a plurality of second sub-light-emitting layers configured to emit light with different wavelengths.

Other detailed matters of the example embodiments are included in the detailed description and the drawings.

According to one or more aspects of the present disclosure, the light-emitting element includes the light-emitting layer that emits light with various wavelengths, which can improve the color reproduction range of the light-emitting element.

According to one or more aspects of the present disclosure, the light-emitting element includes the plurality of light-emitting layers, which can improve the brightness of the light-emitting element.

According to one or more aspects of the present disclosure, it is possible to improve the film quality of the plurality of light-emitting layers.

The effects according to the present disclosure are not limited to the contents exemplified above, and more various effects are included in the present specification.

### BRIEF DESCRIPTION OF THE DRAWINGS

The above and other aspects, features and other advantages of the present disclosure will be more clearly understood from the following detailed description taken in conjunction with the accompanying drawings, in which:

FIG. 1 is a schematic cross-sectional view of a light-emitting element according to an embodiment of the present disclosure;

FIG. 2 is a schematic cross-sectional view of a light-emitting element according to another embodiment of the present disclosure;

FIGS. 3A and 3B are views for explaining an effect of the light-emitting element according to various embodiments of the present disclosure;

FIG. 4 is a schematic configuration view of a display device according to the embodiment of the present disclosure; and

FIG. 5 is a cross-sectional view of a pixel area of the display device according to the embodiment of the present disclosure.

### DETAILED DESCRIPTION OF THE EMBODIMENTS

Advantages and characteristics of the present disclosure and a method of achieving the advantages and characteristics will be clear by referring to example embodiments described below in detail together with the accompanying drawings. However, the present disclosure is not limited to the example embodiments disclosed herein but will be implemented in various forms. The example embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the example embodiments of the present disclosure are merely examples, and the present disclosure is not limited thereto. Like reference numerals generally denote like elements throughout the specification. Further, in the following description of the present disclosure, a detailed explanation of known related technologies can be omitted to avoid unnecessarily obscuring the subject matter of the present disclosure. The terms such as “including,” “having,” and “consist of” used herein are generally intended to allow other components to be added unless the terms are used with the term “only”. Any references to singular can include plural unless expressly stated otherwise.

Components are interpreted to include an ordinary error range even if not expressly stated.

When the position relation between two parts is described using the terms such as “on”, “above”, “below”, and “next”, one or more parts can be positioned between the two parts unless the terms are used with the term “immediately” or “directly”.

When an element or layer is disposed “on” another element or layer, another layer or another element can be interposed directly on the other element or therebetween.

Although the terms “first”, “second”, and the like are used for describing various components, these components are not confined by these terms. These terms are merely used for distinguishing one component from the other components, and may not define order or sequence. Therefore, a first component to be mentioned below can be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated. Further, the term “can” fully encompasses all the meanings and coverages of the term “may.”

The features of various embodiments of the present disclosure can be partially or entirely adhered to or combined with each other and can be interlocked and operated in technically various ways, and the embodiments can be carried out independently of or in association with each other.

Hereinafter, various 41 embodiments of the present disclosure will be described in detail with reference to the drawings. All the components of each light-emitting element and each device using such element according to all embodiments of the present disclosure are operatively coupled and configured.

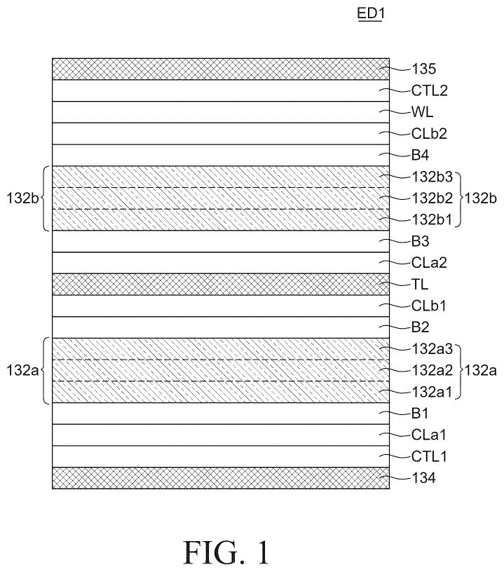

FIG. 1 is a schematic cross-sectional view of a light-emitting element according to an embodiment of the present disclosure.

With reference to FIG. 1, a light-emitting element ED1 can include a first electrode 134, a first contact layer CTL1, a first-first type clad layer CLa1, a first barrier layer B1, a first light-emitting layer 132a, a second barrier layer B2, a second-first type clad layer CLb1, a tunnel layer TL, a first-second type clad layer CLa2, a third barrier layer B3, a second light-emitting layer 132b, a fourth barrier layer B4, a second-second type clad layer CLb2, a window layer WL, a second contact layer CTL2, and a second electrode 135.

The light-emitting element ED1 can have various structures such as lateral, vertical, and flip-chip structures. The lateral light-emitting element includes the first and second electrodes horizontally disposed at two opposite sides of a light-emitting layer. The vertical light-emitting element includes the first and seconds electrodes disposed at upper and lower sides of the light-emitting layer. The flip-chip light-emitting element is substantially identical in structure to the lateral light-emitting element. The lateral light-emitting element has the first and second electrodes horizontally disposed at the upper side of the light-emitting layer, whereas the flip-chip light-emitting element has the first and second electrodes horizontally disposed at the lower side of the light-emitting layer. Hereinafter, the description is made on the assumption that the light-emitting element ED1 has the vertical structure. However, the types of the light-emitting elements ED1 are not limited thereto.

The light-emitting element ED1 can emit light beams with various colors in accordance with emission wavelengths of the light-emitting layers. For example, the light-emitting element ED1 can emit light beams with various colors such as red, green, blue, and the like. Hereinafter, the description will be made on the assumption that the light-emitting element ED1 is a red light-emitting element, and the first light-emitting layer 132a and the second light-emitting layer 132b emit light beams with wavelengths in a red region. However, the light-emitting element ED1 can be a light-emitting element configured to emit light with various wavelengths. The light-emitting element ED1 can be a light-emitting element configured to emit light with a green or blue color.

The first electrode 134 can be disposed at a lower side of the light-emitting element ED1.

The first electrode 134 can be made of an electrically conductive material, for example, a transparent conductive material such as indium tin oxide (ITO) or indium zinc oxide (IZO) or an opaque conductive material such as titanium (Ti), gold (Au), silver (Ag), copper (Cu), or an alloy thereof. However, the present disclosure is not limited thereto.

The first electrode 134 can be disposed adjacent to the first-first type clad layer CLa1 of the light-emitting element ED1. Therefore, in case that the first-first type clad layer CLa1 is a semiconductor layer doped with n-type impurities, the first electrode 134 can be referred to as an n-electrode. However, the present disclosure is not limited thereto.

The first contact layer CTL1 can be disposed above the first electrode 134.

The first contact layer CTL1 can be disposed between the first electrode 134 and the first-first type clad layer CLa1 and improve ohmic properties between the first electrode 134 and the first-first type clad layer CLa1.

The first-first type clad layer CLa1 can be disposed above the first contact layer CTL1.

The first-first type clad layer CLa1 can be a semiconductor layer disposed to inject electrons into the first light-emitting layer 132a. For example, the first-first type clad layer CLa1 can be a layer doped with a material, such as aluminum indium phosphide (AlInP), with n-type and p-type impurities. In this case, the p-type impurity can be magnesium (Mg), zinc (Zn), beryllium (Be), or the like. The n-type impurity can be silicon (Si), germanium, tin (Sn), or the like. However, the present disclosure is not limited thereto. In the present specification, the first-first type clad layer CLa1 can be a layer doped with n-type impurities and referred to as a first semiconductor layer. However, the present disclosure is not limited thereto.

The first barrier layer B1 can be disposed on the first-first type clad layer CLa1.

The first barrier layer B1 can inhibit holes from moving over the first barrier layer B1 from the first light-emitting layer 132a and facilitate the coupling between electrons and holes. Therefore, the first barrier layer B1 disposed adjacent to the first-first type clad layer CLa1, e.g., an n-type semiconductor layer among the plurality of barrier layers disposed in the light-emitting element ED1, can have a larger band gap than the fourth barrier layer B4 disposed adjacent to the second-second type clad layer CLb2, e.g., a p-type semiconductor layer.

The first barrier layer B1 can be made of a material such as aluminum gallium indium phosphide (AlGaInP). However, the present disclosure is not limited thereto.

The first light-emitting layer 132a can be disposed above the first barrier layer B1.

The first light-emitting layer 132a can emit light by receiving holes and electrons from the first-first type clad layer CLa1 and the second-second type clad layer CLb2. For example, in case that the first-first type clad layer CLa1 is a semiconductor layer doped with n-type impurities and the second-second type clad layer CLb2 is a semiconductor layer doped with p-type impurities, the first light-emitting layer 132a can receive electrons, which have moved upward from the first-first type clad layer CLa1, and holes, which have moved downward from the second-second type clad layer CLb2, and emit light as the electrons and the holes are coupled. The first light-emitting layer 132a can be configured as a single layer or a multi-quantum well (MQW) structure. However, the present disclosure is not limited thereto.

The first light-emitting layer 132a can include a plurality of first sub-light-emitting layers configured to emit light beams with different wavelengths. For example, the plurality of first sub-light-emitting layers can include a first-first sub-light-emitting layer 132a1, a first-second sub-light-emitting layer 132a2 disposed on the first-first sub-light-emitting layer 132a1, and a first-third sub-light-emitting layer 132a3 disposed on the first-second sub-light-emitting layer 132a2.

The plurality of first sub-light-emitting layers can be made of a material such as aluminum gallium indium phosphide (AlGaInP).

Meanwhile, the plurality of first sub-light-emitting layers can have different aluminum contents. The aluminum contents of the plurality of first sub-light-emitting layers can increase in one direction. For example, the aluminum contents of the plurality of first sub-light-emitting layers can increase in the downward direction. For example, in case that the n-type semiconductor layer is disposed at the lower side of the light-emitting element ED1 and the p-type semiconductor layer is disposed at the upper side of the light-emitting element ED1, the aluminum contents of the plurality of first sub-light-emitting layers can increase as the plurality of first sub-light-emitting layers becomes closer to the n-type semiconductor layer. The aluminum content of the first-first sub-light-emitting layer 132al can be 0.18% to 0.19%, the aluminum content of the first-second sub-light-emitting layer 132a2 can be 0.17% to 0.18%, and the aluminum content of the first-third sub-light-emitting layer 132a3 can be 0.16% to 0.17%.

Therefore, the emission wavelengths of the plurality of first sub-light-emitting layers can increase in one direction. Specifically, the emission wavelengths of the plurality of first sub-light-emitting layers can increase in the upward direction. For example, in case that the n-type semiconductor layer is disposed at the lower side of the light-emitting element ED1 and the p-type semiconductor layer is disposed at the upper side of the light-emitting element ED1, the emission wavelengths of the plurality of first sub-light-emitting layers can increase as the plurality of first sub-light-emitting layers becomes closer to the p-type semiconductor layer. The first-first sub-light-emitting layer 132al can emit light with a wavelength of 616 nm, the first-second sub-light-emitting layer 132a2 light with a wavelength of 618 nm, and the first-third sub-light-emitting layer 132a3 can emit light with a wavelength of 620 nm.

Meanwhile, the materials, which constitute the plurality of first sub-light-emitting layers, and the emission wavelength bands of the plurality of first sub-light-emitting layers are not limited thereto.

The second barrier layer B2 can be disposed on the first light-emitting layer 132a.

The second barrier layer B2 can be disposed to facilitate the coupling between electrons and holes and made of a material such as aluminum gallium indium phosphide (AlGaInP). However, the present disclosure is not limited thereto.

The second-first type clad layer CLb1 can be disposed on the second barrier layer B2.

The second-first type clad layer CLb1 can be a semiconductor layer disposed to inject holes into the first light-emitting layer 132a. For example, the second-first type clad layer CLb1 can be a layer doped with a material, such as aluminum indium phosphide (AlInP), with n-type and p-type impurities. In this case, the p-type impurity can be magnesium (Mg), zinc (Zn), beryllium (Be), or the like. The n-type impurity can be silicon (Si), germanium, tin (Sn), or the like. However, the present disclosure is not limited thereto. In the present specification, the second-first type clad layer CLb1 is defined as a p-type semiconductor layer, e.g., a layer doped with p-type impurities. However, the present disclosure is not limited thereto.

Meanwhile, the light-emitting element ED1 may not include the second-first type clad layer CLb1 to reduce costs and the number of processes of manufacturing the light-emitting element ED1. However, the present disclosure is not limited thereto.

The tunnel layer TL can be disposed on the second-first type clad layer CLb1.

The tunnel layer TL can be disposed between the first light-emitting layer 132a and the second light-emitting layer 132b and improve the luminous efficiency and color reproduction range of the light-emitting element ED1.

The first-second type clad layer CLa2 can be disposed on the tunnel layer TL.

The first-second type clad layer CLa2 can be a semiconductor layer disposed to inject electrons into the second light-emitting layer 132b. For example, the first-second type clad layer CLa2 can be a layer doped with a material, such as aluminum indium phosphide (AlInP), with n-type and p-type impurities. In this case, the p-type impurity can be magnesium (Mg), zinc (Zn), beryllium (Be), or the like. The n-type impurity can be silicon (Si), germanium, tin (Sn), or the like. However, the present disclosure is not limited thereto. In the present specification, the first-second type clad layer CLa2 is defined as an n-type semiconductor layer, e.g., a layer doped with n-type impurities. However, the present disclosure is not limited thereto.

Meanwhile, the light-emitting element ED1 may not include the first-second type clad layer CLa2 to reduce costs and the number of processes of manufacturing the light-emitting element ED1. However, the present disclosure is not limited thereto.

The third barrier layer B3 can be disposed on the first-second type clad layer CLa2. The third barrier layer B3 can facilitate the coupling between electrons and holes. The third barrier layer B3 can be made of a material such as aluminum gallium indium phosphide (AlGaInP). However, the present disclosure is not limited thereto.

The second light-emitting layer 132b can be disposed on the third barrier layer B3. The second light-emitting layer 132b can emit light by receiving holes and electrons from the first-first type clad layer CLa1 and the second-second type clad layer CLb2. For example, in case that the first-first type clad layer CLa1 is a semiconductor layer doped with n-type impurities and the second-second type clad layer CLb2 is a semiconductor layer doped with p-type impurities, the second light-emitting layer 132b can receive electrons, which have moved upward from the first-first type clad layer CLa1, and holes, which have moved downward from the second-second type clad layer CLb2, and emit light as the electrons and the holes are coupled. The second light-emitting layer 132b can be configured as a single layer or a multi-quantum well (MQW) structure. However, the present disclosure is not limited thereto.

The second light-emitting layer 132b can emit light with a wavelength different from a wavelength of the light emitted from the first light-emitting layer 132a. For example, the second light-emitting layer 132b and the first light-emitting layer 132a can be made of different materials.

The second light-emitting layer 132b can include a plurality of second sub-light-emitting layers configured to emit light beams with different wavelengths. For example, the plurality of second sub-light-emitting layers can include a second-first sub-light-emitting layer 132b1, a second-second sub-light-emitting layer 132b2 disposed on the second-first sub-light-emitting layer 132b1, and a second-third sub-light-emitting layer 132b3 disposed on the second-second sub-light-emitting layer 132b2.

The plurality of second sub-light-emitting layers can be made of aluminum gallium indium phosphide (AlGaInP). Meanwhile, the plurality of second sub-light-emitting layers can have different aluminum contents. In this case, the aluminum contents of the plurality of second sub-light-emitting layers can increase in one direction. For example, the aluminum contents of the plurality of second sub-light-emitting layers can increase in the downward direction. For example, in case that the n-type semiconductor layer is disposed at the lower side of the light-emitting element ED1 and the p-type semiconductor layer is disposed at the upper side of the light-emitting element ED1, the aluminum contents of the plurality of second sub-light-emitting layers can increase as the plurality of second sub-light-emitting layers becomes closer to the n-type semiconductor layer. The aluminum content of the second-first sub-light-emitting layer 132b1 can be 0.13% to 0.14%, the aluminum content of the second-second sub-light-emitting layer 132b2 can be 0.12% to 0.13%, and the aluminum content of the second-third sub-light-emitting layer 132b3 can be 0.11% to 0.12%.

Therefore, the emission wavelengths of the plurality of second sub-light-emitting layers can increase in one direction. Specifically, the emission wavelengths of the plurality of second sub-light-emitting layers can increase in the upward direction. For example, in case that the n-type semiconductor layer is disposed at the lower side of the light-emitting element ED1 and the p-type semiconductor layer is disposed at the upper side of the light-emitting element ED1, the emission wavelengths of the plurality of second sub-light-emitting layers can increase as the plurality of second sub-light-emitting layers becomes closer to the p-type semiconductor layer. The second-first sub-light-emitting layer 132b1 can emit light with a wavelength of 626 nm, the second-second sub-light-emitting layer 132b2 can emit light with a wavelength of 628 nm, and the second-third sub-light-emitting layer 132b3 can emit light with a wavelength of 630 nm. However, the present disclosure is not limited thereto.

Meanwhile, the materials, which constitute the plurality of second sub-light-emitting layers, and the emission wavelength bands of the plurality of second sub-light-emitting layers are not limited thereto.

The fourth barrier layer B4 can be disposed on the second light-emitting layer 132b.

The fourth barrier layer B4 can inhibit electrons from moving over from the second light-emitting layer 132b in a direction in which the fourth barrier layer B4 is disposed. The fourth barrier layer B4 can facilitate the coupling between electrons and holes.

The fourth barrier layer B4 can be made of a material such as aluminum gallium indium phosphide (AlGaInP). However, the present disclosure is not limited thereto.

The second-second type clad layer CLb2 can be disposed on the fourth barrier layer B4.

The second-second type clad layer CLb2 can be a semiconductor layer disposed to inject holes into the second light-emitting layer 132b. For example, the second-second type clad layer CLb2 can be a layer doped with a material, such as aluminum indium phosphide (AlInP), with n-type and p-type impurities. In this case, the p-type impurity can be magnesium (Mg), zinc (Zn), beryllium (Be), or the like. The n-type impurity can be silicon (Si), germanium, tin (Sn), or the like. However, the present disclosure is not limited thereto. In the present specification, the second-second type clad layer CLb2 can be a layer doped with p-type impurities and referred to as a second semiconductor layer. However, the present disclosure is not limited thereto.

The window layer WL can be disposed on the second-second type clad layer CLb2. In order to improve the light extraction efficiency, the window layer WL can be disposed on the second-second type clad layer CLb2 disposed at the upper side of the light-emitting element ED1 between the first-first type clad layer CLa1 and the second-second type clad layer CLb2.

The second contact layer CTL2 can be disposed above the window layer WL. The second contact layer CTL2 can be disposed between the second electrode 135 and the second-second type clad layer CLb2 and improve ohmic properties between the second electrode 135 and the second-second type clad layer CLb2. For example, the second contact layer CTL2 can be a semiconductor layer doped with a gallium phosphide (GaP) material with carbon (C). However, the present disclosure is not limited thereto.

The second electrode 135 can be disposed on the second contact layer CTL2. The second electrode 135 can be made of an electrically conductive material, for example, a transparent conductive material such as indium tin oxide (ITO) or indium zinc oxide (IZO) or an opaque conductive material such as titanium (Ti), gold (Au), silver (Ag), copper (Cu), or an alloy thereof. However, the present disclosure is not limited thereto.

The second electrode 135 can be disposed adjacent to the second-second type clad layer CLb2 of the light-emitting element ED1. Therefore, in case that the second-second type clad layer CLb2 is a layer doped with p-type impurities, the second electrode 135 can be referred to as a p-electrode. However, the present disclosure is not limited thereto.

The light-emitting element ED1 according to the embodiment of the present disclosure includes the first light-emitting layer 132a including the plurality of first sub-light-emitting layers, and the second light-emitting layer 132b including the plurality of second sub-light-emitting layers. Therefore, the brightness of the light-emitting element ED1 can be improved, and the luminous efficiency of the light-emitting element ED1 can be improved.

In addition, the plurality of first sub-light-emitting layers and the plurality of second sub-light-emitting layers of the light-emitting element ED1 according to the embodiment of the present disclosure emit light beams with different wavelengths. Therefore, the light-emitting element ED1 can emit light beams in various wavelength bands, such that the color reproduction range of the light-emitting element ED1 can be improved.

The display device includes the light-emitting elements configured to emit light beams with various wavelengths to implement various colors. Meanwhile, the brightness and luminous efficiency of the light-emitting elements can vary depending on the emission wavelengths of the light-emitting elements. For example, the luminous efficiency of the light-emitting element configured to emit red light is lower than the luminous efficiency of the blue light-emitting element and the green light-emitting element. Therefore, in case that all the light-emitting elements of the display device operate to exhibit maximum brightness, the brightness of the red light can be relatively lower than the brightness of the blue light and the brightness of the green light. Therefore, there can be a limitation in that a brightness deviation can occur in accordance with colors in the display device.

Therefore, in the light-emitting element ED1 according to the embodiment of the present specification, the plurality of first sub-light-emitting layers and the plurality of second sub-light-emitting layers emit red light beams with different wavelengths. As such, the light-emitting element ED1 according to the embodiment of the present disclosure can improve the brightness and luminous efficiency in comparison with the red light-emitting element in which the light-emitting layer configured to emit light with a single wavelength is disposed. For example, the brightness of the light-emitting element ED1, which emits red light, can be improved to a level corresponding to the maximum brightness of the green light-emitting element and the maximum brightness of the blue light-emitting element. Thus, the light-emitting element ED1 according to the embodiments of the present disclosure can solve or address the problem or limitations of the occurrence of a brightness deviation in accordance with the colors.

In addition, the light-emitting layer of the red light-emitting element can have a smaller band gap than the light-emitting layer of the light-emitting element configured to emit light with another color. The band gap of the light-emitting layer can be easily adjusted, and the emission wavelength can be easily adjusted. Therefore, in the light-emitting element ED1 according to the embodiment of the present disclosure, the emission wavelengths of the plurality of first sub-light-emitting layers and the plurality of second sub-light-emitting layers of the red light-emitting element can be easily adjusted.

In addition, in the light-emitting element ED1 according to the embodiment of the present disclosure, the aluminum contents of the plurality of first sub-light-emitting layers and the plurality of second sub-light-emitting layers can increase from one surface in contact with the first-first type clad layer CLa1, toward the other surface that is in contact with the second-second type clad layer CLb2. Therefore, it is possible to mitigate a lattice parameter difference occurring on the interfaces between the plurality of first sub-light-emitting layers and the plurality of second sub-light-emitting layers. Therefore, the film quality of the light-emitting element ED1 can be improved.

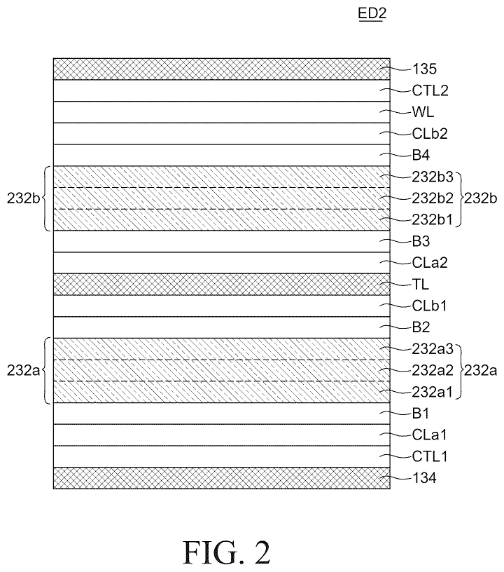

FIG. 2 is a schematic cross-sectional view of a light-emitting element according to another embodiment of the present disclosure. A light-emitting element ED2 in FIG. 2 is substantially identical in configuration to the light-emitting element ED1 in FIG. 1, except for a first light-emitting layer 232a and a second light-emitting layer 232b. Therefore, repeated descriptions of the identical components will be omitted or may be briefly provided.

With reference to FIG. 2, the first light-emitting layer 232a can include a plurality of first sub-light-emitting layers configured to emit light beams with different wavelengths. For example, the plurality of first sub-light-emitting layers can include a first-first sub-light-emitting layer 232al, a first-second sub-light-emitting layer 232a2 disposed on the first-first sub-light-emitting layer 232a1, and a first-third sub-light-emitting layer 232a3 disposed on the first-second sub-light-emitting layer 232a2.

The plurality of first sub-light-emitting layers can be made of a material such as aluminum gallium indium phosphide (AlGaInP).

Meanwhile, the plurality of first sub-light-emitting layers can have different aluminum contents. The aluminum contents of the plurality of first sub-light-emitting layers can increase in one direction. For example, the aluminum contents of the plurality of first sub-light-emitting layers can increase in the upward direction. For example, in case that the n-type semiconductor layer is disposed at the lower side of the light-emitting element ED2 and the p-type semiconductor layer is disposed at the upper side of the light-emitting element ED2, the aluminum contents of the plurality of first sub-light-emitting layers can increase as the plurality of first sub-light-emitting layers becomes closer to the p-type semiconductor layer. The aluminum content of the first-first sub-light-emitting layer 232al can be 0.11% to 0.12%, the aluminum content of the first-second sub-light-emitting layer 232a2 can be 0.12% to 0.13%, and the aluminum content of the first-third sub-light-emitting layer 232a3 can be 0.13% to 0.14%.

Therefore, the emission wavelengths of the plurality of first sub-light-emitting layers can increase in one direction. Specifically, the emission wavelengths of the plurality of first sub-light-emitting layers can increase in the downward direction. For example, in case that the n-type semiconductor layer is disposed at the lower side of the light-emitting element ED2 and the p-type semiconductor layer is disposed at the upper side of the light-emitting element ED2, the emission wavelengths of the plurality of first sub-light-emitting layers can increase as the plurality of first sub-light-emitting layers becomes closer to the n-type semiconductor layer. The first-first sub-light-emitting layer 232al can emit light with a wavelength of 630 nm, the first-second sub-light-emitting layer 232a2 can emit light with a wavelength of 628 nm, and the first-third sub-light-emitting layer 232a3 can emit light with a wavelength of 626 nm.

Meanwhile, the materials, which constitute the plurality of first sub-light-emitting layers, and the emission wavelength bands of the plurality of first sub-light-emitting layers are not limited thereto.

With reference to FIG. 2, the second light-emitting layer 232b can be disposed on the third barrier layer B3.

The second light-emitting layer 232b can emit light with a wavelength different from a wavelength of the light emitted from the first light-emitting layer 232a. For example, the second light-emitting layer 232b and the first light-emitting layer 232a can be made of different materials.

The second light-emitting layer 232b can include a plurality of second sub-light-emitting layers configured to emit light beams with different wavelengths. For example, the plurality of second sub-light-emitting layers can include a second-first sub-light-emitting layer 232b1, a second-second sub-light-emitting layer 232b2 disposed on the second-first sub-light-emitting layer 232b1, and a second-third sub-light-emitting layer 232b3 disposed on the second-second sub-light-emitting layer 232b2.

The plurality of second sub-light-emitting layers can be made of aluminum gallium indium phosphide (AlGaInP). Meanwhile, the plurality of second sub-light-emitting layers can have different aluminum contents. In this case, the aluminum contents of the plurality of second sub-light-emitting layers can increase in one direction. For example, the aluminum contents of the plurality of second sub-light-emitting layers can increase in the upward direction. For example, in case that the n-type semiconductor layer is disposed at the lower side of the light-emitting element ED2 and the p-type semiconductor layer is disposed at the upper side of the light-emitting element ED2, the aluminum contents of the plurality of second sub-light-emitting layers can increase as the plurality of second sub-light-emitting layers becomes closer to the p-type semiconductor layer. The aluminum content of the second-first sub-light-emitting layer 232b1 can be 0.16% to 0.17%, the aluminum content of the second-second sub-light-emitting layer 232b2 can be 0.17% to 0.18%, and the aluminum content of the second-third sub-light-emitting layer 232b3 can be 0.18% to 0.19%.

Therefore, the emission wavelengths of the plurality of second sub-light-emitting layers can increase in one direction. Specifically, the emission wavelengths of the plurality of second sub-light-emitting layers can increase in the downward direction. For example, in case that the n-type semiconductor layer is disposed at the lower side of the light-emitting element ED2 and the p-type semiconductor layer is disposed at the upper side of the light-emitting element ED2, the emission wavelengths of the plurality of second sub-light-emitting layers can increase as the plurality of second sub-light-emitting layers becomes closer to the n-type semiconductor layer. The second-first sub-light-emitting layer 232b1 can emit light with a wavelength of 620 nm, the second-second sub-light-emitting layer 232b2 can emit light with a wavelength of 618 nm, and the second-third sub-light-emitting layer 232b3 can emit light with a wavelength of 616 nm. However, the present disclosure is not limited thereto.

Meanwhile, the materials, which constitute the plurality of second sub-light-emitting layers, and the emission wavelength bands of the plurality of second sub-light-emitting layers are not limited thereto.

The light-emitting element ED2 according to another embodiment of the present disclosure includes the first light-emitting layer 232a including the plurality of first sub-light-emitting layers, and the second light-emitting layer 232b including the plurality of second sub-light-emitting layers. Therefore, the brightness of the light-emitting element ED2 can be improved, and the luminous efficiency of the light-emitting element ED2 can be improved.

The plurality of first sub-light-emitting layers and the plurality of second sub-light-emitting layers of the light-emitting element ED2 according to another embodiment of the present disclosure emit light beams with different wavelengths. Therefore, the color reproduction range of the light-emitting element ED2 can be improved.

In the light-emitting element ED2 according to another embodiment of the present disclosure, the plurality of first sub-light-emitting layers and the plurality of second sub-light-emitting layers emit red light beams with different wavelengths. Therefore, the light-emitting element ED2 according to another embodiment of the present disclosure can solve the problem of the occurrence of a brightness deviation in accordance with the colors, and the emission wavelengths of the plurality of first sub-light-emitting layers and the plurality of second sub-light-emitting layers of the red light-emitting element can be easily adjusted.

In addition, in the light-emitting element ED2 according to another embodiment of the present disclosure, the aluminum contents of the plurality of first sub-light-emitting layers and the plurality of second sub-light-emitting layers can increase in one direction. Therefore, it is possible to mitigate a lattice parameter difference occurring on the interfaces between the plurality of first sub-light-emitting layers and the plurality of second sub-light-emitting layers.

In the light-emitting element ED2 according to another embodiment of the present disclosure, the emission wavelengths of the plurality of first sub-light-emitting layers and the plurality of second sub-light-emitting layers can decrease in the upward direction of the light-emitting element ED2. In the general light-emitting element, the transmittance of the light-emitting layer, which emits light in a long wavelength band, is lower than the transmittance of the light-emitting layer that emits light in a short wavelength band. Therefore, in the light-emitting element ED2 according to another embodiment of the present disclosure, the first-first sub-light-emitting layer 232al disposed at the lower side of the light-emitting element ED2, emits light in the longest wavelength band, and the second-third sub-light-emitting layer 232b3 disposed at the upper side of the light-emitting element ED2, emits light in the shortest wavelength band. Therefore, the transmittance of the light-emitting element ED2 can be improved.

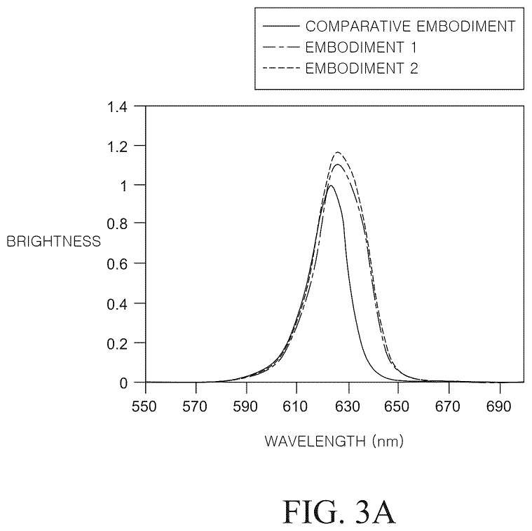

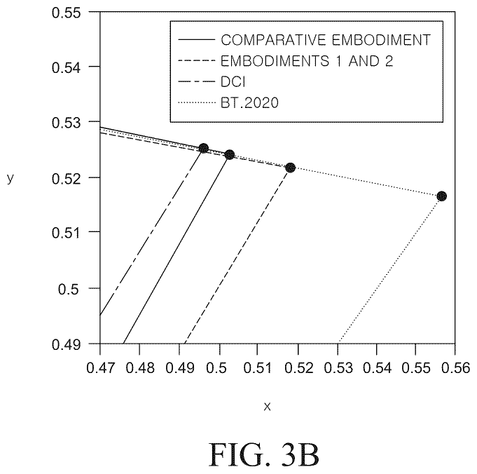

FIGS. 3A and 3B are views for explaining an effect of the light-emitting element according to various embodiments of the present disclosure. Particularly, FIG. 3A illustrates emission spectrum simulation results related to the comparative embodiment and Embodiments 1 and 2. In FIG. 3A, the maximum brightness of the comparative embodiment is assumed to be 1. FIG. 3B illustrates CIE coordinate systems for the comparative embodiment and Embodiments 1 and 2.

The comparative embodiment is related to a general light-emitting element, e.g., a light-emitting element in which a light-emitting layer, which emits light in a single wavelength, is disposed. Embodiment 1 is related to the light-emitting element ED1 in FIG. 1, in which the aluminum contents of the plurality of first sub-light-emitting layers and the plurality of second sub-light-emitting layers increase as the plurality of first sub-light-emitting layers and the plurality of second sub-light-emitting layers become closer to the n-type semiconductor layer between the n-type layer semiconductor and the p-type semiconductor layer. Embodiment 1 includes the first-first sub-light-emitting layer configured to emit light with a wavelength of 616 nm, the first-second sub-light-emitting layer configured to emit light with a wavelength of 618 nm, the first-third sub-light-emitting layer configured to emit light with a wavelength of 620 nm, the second-first sub-light-emitting layer configured to emit light with a wavelength of 626 nm, the second-second sub-light-emitting layer configured to emit light with a wavelength of 628 nm, and the second-third sub-light-emitting layer configured to emit light with a wavelength of 630 nm. Embodiment 2 is related to the light-emitting element ED2 in FIG. 2, in which the aluminum contents of the plurality of first sub-light-emitting layers and the plurality of second sub-light-emitting layers increase as the plurality of first sub-light-emitting layers and the plurality of second sub-light-emitting layers become closer to the p-type semiconductor layer between the n-type semiconductor layer and the p-type semiconductor layer. Embodiment 2 includes the first-first sub-light-emitting layer configured to emit light with a wavelength of 630 nm, the first-second sub-light-emitting layer configured to emit light with a wavelength of 628 nm, the first-third sub-light-emitting layer configured to emit light with a wavelength of 626 nm, the second-first sub-light-emitting layer configured to emit light with a wavelength of 620 nm, the second-second sub-light-emitting layer configured to emit light with a wavelength of 618 nm, and the second-third sub-light-emitting layer configured to emit light with a wavelength of 616 nm.

First, with reference to FIG. 3A, it can be ascertained that the maximum brightness in the comparative embodiment is 1, the maximum brightness in Embodiment 1 is about 1.1, and the maximum brightness in Embodiment 2 is about 1.16. Therefore, it can be ascertained that the maximum brightness in Embodiments 1 and 2 is higher than the maximum brightness in the comparative embodiment. It can be ascertained that the maximum brightness in Embodiment 2 is higher than the maximum brightness in Embodiment 1.

In addition, with reference to FIG. 3A, it can be ascertained that the wavelength width in Embodiments 1 and 2 is larger than the wavelength width in the comparative embodiment. It can be ascertained that the wavelength width in Embodiment 2 is larger than the wavelength width in Embodiment 1.

Next, with reference to FIG. 3B, it can be ascertained that the x-coordinate in Embodiments 1 and 2 is further moved in the +direction than the x-coordinate in the comparative embodiment, and the y-coordinate in Embodiments 1 and 2 is further moved in the −direction than the y-coordinate in the comparative embodiment. Therefore, it can be ascertained that the red regions in Embodiments 1 and 2 are expanded.

Hereinafter, the description will be made with reference to Table 1.

Table 1 shows color reproduction ranges in the comparative embodiment and Embodiments 1 and 2. Table 1 shows color reproduction ranges in the comparative embodiment and Embodiments 1 and 2 based on BT.2020.

TABLE 1

| | Color Reproduction Range (%) |
|---|---|
| Comparative Embodiment | 87.4 |
| Embodiment 1 | 90.4 |
| Embodiment 2 | 90.4 |

With reference to Table 1, it can be ascertained that the color reproduction range in Embodiments 1 and 2 of the present disclosure is higher by about 3% than the color reproduction range in the comparative embodiment. Therefore, it can be ascertained that the color reproduction range in Embodiments 1 and 2 is larger than the color reproduction range in the comparative embodiment.

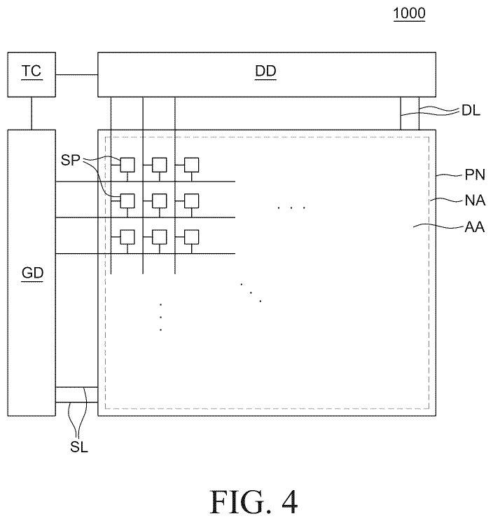

FIG. 4 is a schematic configuration view of a display device according to the embodiment of the present disclosure. For convenience of description, FIG. 4 illustrates a display panel PN, a gate drive part GD, a data drive part DD, and a timing controller TC among various constituent elements of a display device 1000.

Referring to FIG. 4, the gate drive part GD supplies a plurality of scan signals to a plurality of scan lines SL in response to a plurality of gate control signals provided from the timing controller TC. FIG. 4 illustrates that the single gate drive part GD is disposed to be spaced apart from one side of the display panel PN. However, the number and arrangement of the gate drive part GD are not limited thereto.

The data drive part DD converts image data inputted from the timing controller TC, into a data voltage by using a reference gamma voltage in response to a plurality of data control signals provided from the timing controller TC. The data drive part DD can supply the converted data voltage to a plurality of data lines DL.

The timing controller TC aligns image data inputted from the outside, and supplies the image data to the data drive part DD. The timing controller TC can generate the gate control signals and the data control signals by using synchronizing signals, e.g., dot clock data signals, enable signals, and horizontal/vertical synchronizing signals inputted from the outside. Further, the timing controller TC can control the gate drive part GD and the data drive part DD by supplying the generated gate control signals and data control signals to the gate drive part GD and the data drive part DD.

The display panel PN is configured to display images to a user and includes the plurality of subpixels SP. In the display panel PN, the plurality of scan lines SL, and the plurality of data lines DL intersect one another, and each of the plurality of subpixels SP is connected to the scan line SL and the data line DL. In addition, the plurality of subpixels SP can be respectively connected to a high-potential power line, a low-potential power line, a reference line, and the like.

The display panel PN can have a display area (or active area) AA, and a non-display area (or non-active area) NA configured to surround the display area AA. The non-display area NA can surround the display area AA entirely or only in part(s).

The display area AA is an area of the display device 1000 in which images are displayed. The display area AA can include the plurality of subpixels SP constituting a plurality of pixels PX, and a circuit configured to operate the plurality of subpixels SP. The plurality of subpixels SP is minimum units that constitute the display area AA. The n subpixels SP can constitute a single pixel. A light-emitting element, a thin-film transistor for operating the light-emitting element, and the like can be disposed in each of the plurality of subpixels SP. The plurality of light-emitting elements can be differently defined depending on the type of the display panel PN. For example, in case that the display panel PN is an inorganic light-emitting display panel, the light-emitting element can be a light-emitting diode (LED) or a micro light-emitting diode (micro LED).

A plurality of lines for transmitting various types of signals to the plurality of subpixels SP is disposed in the display area AA. For example, the plurality of lines can include the plurality of data lines DL for supplying data voltages to the plurality of subpixels SP, and the plurality of scan lines SL for supplying scan signals to the plurality of subpixels SP. The plurality of scan lines SL can extend in one direction in the display area AA and be connected to the plurality of subpixels SP. The plurality of data lines DL can extend in a direction different from one direction in the display area AA and be connected to the plurality of subpixels SP. In addition, a low-potential power line, a high-potential power line, and the like can be further disposed in the display area AA. However, the present disclosure is not limited thereto.

The non-display area NA can be defined as an area in which no image is displayed, e.g., an area extending from the display area AA. The non-display area NA can include link lines and pad electrodes for transmitting signals to the subpixels SP in the display area AA. Alternatively, the non-display area NA can include drive ICs such as gate drivers IC and data drivers IC.

However, the non-display area NA can be positioned on a rear surface of the display panel PN, e.g., a surface on which the subpixel SP is not present. Alternatively, the non-display area NA can be excluded. However, the present disclosure is not limited to the configuration illustrated in the drawings.

Meanwhile, the drive parts such as the gate drive part GD, the data drive part DD, and the timing controller TC can be connected to the display panel PN in various ways. For example, the gate drive part GD can be mounted in the non-display area NA by a gate-in-panel (GIP) method or mounted between the plurality of subpixels SP by a gate-in-active area (GIA) method in the display area AA. For example, the data drive part DD and the timing controller TC can be formed on a separate flexible film and the printed circuit board PCB. The data drive part DD and the timing controller TC can be electrically connected to the display panel PN by bonding the flexible film and the printed circuit board PCB to the pad electrode formed in the non-display area NA of the display panel PN.

In case that the gate drive part GD is mounted by the GIP method and the data drive part DD and the timing controller TC transmit signals to the display panel PN through the pad electrode in the non-display area NA, it is necessary to ensure an area of the non-display area NA at a predetermined level or higher in order to dispose the gate drive part GD and the pad electrode, which can increase a bezel.

Alternatively, in case that the gate drive part GD is mounted in the display area AA by the GIA method and a side line, which connects a signal line on a front surface of the display panel PN to the pad electrode on the rear surface of the display panel PN, is formed to bond the flexible film and the printed circuit board to the rear surface of the display panel PN, it is possible to minimize the non-display area NA on the front surface of the display panel PN. For example, in case that the gate drive part GD, the data drive part DD, and the timing controller TC are connected to the display panel PN by the above-mentioned method, a zero bezel in which the bezel is not substantially present can be implemented.

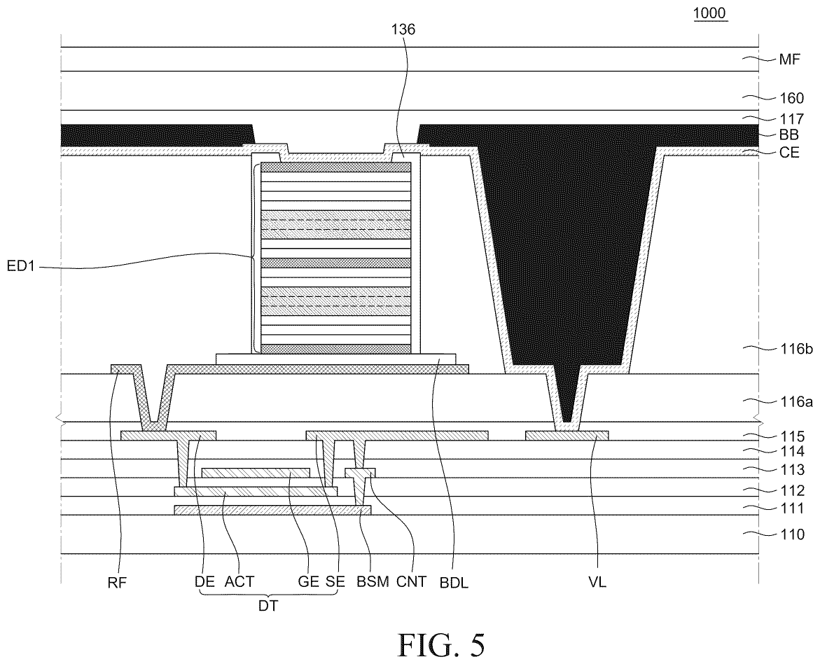

Hereinafter, one subpixel SP of the display device 1000 according to the embodiment of the present disclosure will be described with reference to FIG. 5. The display device 1000 can have the plurality of sub-pixels each having the configuration shown in FIG. 5.

FIG. 5 is a cross-sectional view of the subpixel according to the embodiment of the present disclosure. For convenience of description, FIG. 5 illustrates a substrate 110, a buffer layer 111, a gate insulation layer 112, a first interlayer insulation layer 113, a second interlayer insulation layer 114, a passivation layer 115, a first planarization layer 116a, a second planarization layer 116b, a bank BB, a protective layer 117, a cover layer 160, an optical film MF, a transistor DT, a light-blocking layer BSM, a reflective plate RF, the light-emitting element ED1, a power line VL, a connection electrode CE, and a bonding layer BDL.

With reference to FIG. 5, the substrate 110 can be a substrate, e.g., an insulation substrate configured to support the constituent elements disposed above the display device 1000. For example, the substrate 110 can be made of glass, resin, or the like. In addition, the substrate 110 can include polymer or plastic. In several embodiments, the substrate 110 can be made of a plastic material having flexibility.

The plurality of pixels can be formed on the substrate 110 so that images can be displayed.

First, the light-blocking layer BSM can be disposed on the substrate 110. The light-blocking layer BSM can block light entering active layers ACT of a plurality of transistors, thereby minimizing a leakage current. For example, the light-blocking layer BSM can be disposed below an active layer ACT of a transistor DT and block light entering the active layer ACT. In case that the light is emitted to the active layer ACT, a leakage current occurs, which can degrade the reliability of the transistor. Therefore, the light-blocking layer BSM for blocking light can be disposed on the substrate 110, thereby improving the reliability of the transistor DT. The light-blocking layer BSM can be made of an opaque electrically conductive material, for example, copper (Cu), aluminum (Al), molybdenum (Mo), nickel (Ni), titanium (Ti), chromium (Cr), or an alloy thereof. However, the present disclosure is not limited thereto.

The buffer layer 111 can be disposed on the light-blocking layer BSM. For example, the buffer layer 111 can be configured as a single layer or multilayer made of silicon oxide (Siox) or silicon nitride (SiNx). However, the present disclosure is not limited thereto. The buffer layer 111 can reduce the penetration of moisture or impurities through the substrate 110. However, the buffer layer 111 can be excluded in accordance with the type of first substrate 110 or the type of transistor. The present disclosure is not limited thereto.

The transistor DT including the active layer ACT, a gate electrode GE, a source electrode SE, and a drain electrode DE can be disposed on the buffer layer 111.

Meanwhile, referring to FIG. 5, an additional buffer layer can be disposed between the substrate 110 and the light-blocking layer BSM. For example, like the buffer layer 111, the additional buffer layer can be configured as a single layer or multilayer made of silicon oxide (Siox) or silicon nitride (SiNx) in order to reduce the penetration of moisture or impurities through the substrate 110. However, the present disclosure is not limited thereto.

First, the active layer ACT of the transistor DT can be disposed on the buffer layer 111. The active layer ACT can be made of a semiconductor material such as an oxide semiconductor, amorphous silicon, or polysilicon. However, the present disclosure is not limited thereto.

In addition, in addition to the transistor DT, other transistors, such as a switching transistor, a sensing transistor, and a light emission control transistor, can be additionally disposed. The active layers of these transistors can be made of a semiconductor material such as an oxide semiconductor, amorphous silicon, or polysilicon. However, the present disclosure is not limited thereto. In addition, the active layers of the transistors, such as the transistor DT, the switching transistor, the sensing transistor, and the light emission control transistor included in pixel circuits, can be made of the same material or different materials.

The gate insulation layer 112 can be disposed on the active layer ACT. The gate insulation layer 112 can be an insulation layer for electrically insulating the active layer ACT and the gate electrode GE. The gate insulation layer 112 can be configured as a single layer or multilayer made of silicon oxide (SiOx) or silicon nitride (SiNx). However, the present disclosure is not limited thereto.

The gate electrode GE can be disposed on the gate insulation layer 112. The gate electrode GE can be made of an electrically conductive material, for example, copper (Cu), aluminum (Al), molybdenum (Mo), nickel (Ni), titanium (Ti), chromium (Cr), or an alloy thereof. However, the present disclosure is not limited thereto.

In addition, an intermediate electrode CNT can be disposed on the gate insulation layer 112. The intermediate electrode CNT can be made of the same material as the gate electrode GE. For example, the intermediate electrode CNT can be made of copper (Cu), aluminum (Al), molybdenum (Mo), nickel (Ni), titanium (Ti), chromium (Cr), or an alloy thereof. The intermediate electrode CNT can be electrically connected to the source electrode SE. However, the present disclosure is not limited thereto.

The first interlayer insulation layer 113 and the second interlayer insulation layer 114 can be disposed on the gate electrode GE. Contact holes, through which the source electrode SE and the drain electrode DE are connected to the active layer ACT, are formed in the first interlayer insulation layer 113 and the second interlayer insulation layer 114. The first interlayer insulation layer 113 and the second interlayer insulation layer 114 are insulation layers for protecting components disposed below the first interlayer insulation layer 113 and the second interlayer insulation layer 114. The first interlayer insulation layer 113 and the second interlayer insulation layer 114 can each be configured as a single layer or multilayer made of silicon oxide (SiOx) or silicon nitride (SiNx). However, the present disclosure is not limited thereto.

The source electrode SE and the drain electrode DE electrically connected to the active layer ACT, can be disposed on the second interlayer insulation layer 114. The drain electrode DE can be electrically connected to the first electrode 134 of the light-emitting element ED1, and the source electrode SE can be connected to another component of the pixel circuit. The source electrode SE and the drain electrode DE can each be made of an electrically conductive material, for example, copper (Cu), aluminum (Al), molybdenum (Mo), nickel (Ni), titanium (Ti), chromium (Cr), or an alloy thereof. However, the present disclosure is not limited thereto.

The power line VL can be disposed on the second interlayer insulation layer 114. The power line VL can be a low-potential power line. In the present specification, the configuration is described in which a low-potential voltage is supplied to the power line VL. However, the present disclosure is not limited thereto. The power line VL can be a high-potential power line. The power line VL can be made of the same material as the source electrode SE and the drain electrode DE. However, the present disclosure is not limited thereto.

The power line VL can be connected to the connection electrode CE. The power line VL can be connected to the second electrode 135 of the light-emitting element ED1 through the connection electrode CE. Therefore, the power line VL can transmit the low-potential voltage to the connection electrode CE and the second electrode 135 of the light-emitting element ED1.

The passivation layer 115 can be disposed on the source electrode SE, the drain electrode DE, and the power line VL. The passivation layer 115 is an insulation layer for protecting components disposed below the passivation layer 115. The passivation layer 115 can be made of an inorganic material such as silicon oxide (Siox) or silicon nitride (SiNx). However, the present disclosure is not limited thereto.

The first planarization layer 116a can be disposed on the passivation layer 115. The first planarization layer 116a can planarize an upper portion of the pixel circuit including the transistor DT. The first planarization layer 116a can be configured as a single layer or multilayer and made of benzocyclobutene or an acrylic-based organic material, for example. However, the present disclosure is not limited thereto.

The plurality of reflective plates RF can be disposed on the first planarization layer 116a. The plurality of reflective plates RF can be disposed below the plurality of light-emitting elements ED1 and electrically connected to the plurality of light-emitting elements ED1. The plurality of reflective plates RF can be configured to reflect the light emitted from the plurality of light-emitting elements ED1, toward the upper side of the substrate 110 and have a shape corresponding to each of the plurality of subpixels SP. The plurality of reflective plates RF can serve to reflect the light emitted from the plurality of light-emitting elements ED1 and serve as electrodes that electrically connect the plurality of light-emitting elements ED1 and the pixel circuit. Specifically, the plurality of reflective plates RF can be electrically connected to the drain electrodes DE of the transistors DT through the contact holes in the passivation layer 115 and the first planarization layer 116a. For example, the plurality of reflective plates RF can be electrically connected to the first electrodes 134 and the transistors DT of the plurality of light-emitting elements ED1.

Therefore, the plurality of reflective plates RF can include various conductive layers in consideration of light reflection efficiency and resistance. For example, the plurality of reflective plates RF can be made by using an opaque conductive layer made of silver (Ag), aluminum (Al), molybdenum (Mo), titanium (Ti), or an alloy thereof, together with a transparent conductive layer made of indium tin oxide (ITO). However, the structures of the plurality of reflective plates RF are not limited thereto.

The plurality of bonding layers BDL can be disposed on the plurality of reflective plates RF. The plurality of bonding layers BDL can fix the plurality of light-emitting elements ED1 disposed on the plurality of reflective plates RF. In addition, the plurality of bonding layers BDL can include an electrically conductive material to electrically connect the plurality of reflective plates RF and the first electrodes 134 of the plurality of light-emitting elements ED1. However, the present disclosure is not limited thereto. The plurality of bonding layers BDL can be made of an insulating material in case that an electrically conductive material is separately disposed to electrically connect the plurality of reflective plates RF and the first electrodes 134 of the plurality of light-emitting elements ED1.

The plurality of light-emitting elements ED1 can be disposed on the plurality of bonding layers BDL in each of the plurality of subpixels SP. The plurality of light-emitting elements ED1 can be disposed on the plurality of bonding layers BDL and electrically connected to the reflective plates RF. Specifically, the first electrodes 134 of the plurality of light-emitting elements ED1 and the reflective plates RF can be electrically connected through the plurality of bonding layers BDL.

The plurality of light-emitting elements ED1 can be elements configured to emit light by the current and include a first light-emitting element configured to emit red light, a second light-emitting element configured to emit green light, and a third light-emitting element configured to emit blue light. A combination of the light-emitting elements ED1 can implement various colors including white. For example, the light-emitting element ED1 can be a light-emitting diode (LED) or a micro LED. However, the present disclosure is not limited thereto.

The plurality of light-emitting elements ED1 can each include the first electrode 134, the first contact layer CTL1, the first-first type clad layer CLa1, the first barrier layer B1, the first light-emitting layer 132a, the second barrier layer B2, the second-first type clad layer CLb1, the tunnel layer TL, the first-second type clad layer CLa2, the third barrier layer B3, the second light-emitting layer 132b, the fourth barrier layer B4, the second-second type clad layer CLb2, the window layer WL, the second contact layer CTL2, and the second electrode 135. Hereinafter, the description is made on the assumption that the plurality of light-emitting elements ED1 has the vertical structure. However, the types of the plurality of light-emitting elements ED1 are not limited thereto. In addition, in FIG. 5, the plurality of light-emitting elements ED1 is described as adopting the light-emitting element ED1 described with reference to FIG. 1. However, the present disclosure is not limited thereto. All the light-emitting elements ED2 according to another embodiment of the present disclosure described with reference to FIG. 2 can be applied. Because the plurality of light-emitting elements ED1 has been described in detail with reference to FIG. 1, a repeated description will be omitted or may be briefly provided.

Next, an encapsulation film 136 can be disposed to surround the plurality of light-emitting elements ED1. The encapsulation film 136 can be made of an insulating material and protect the first electrode 134, the first contact layer CTL1, the first-first type clad layer CLa1, the first barrier layer B1, the first light-emitting layer 132a, the second barrier layer B2, the second-first type clad layer CLb1, the tunnel layer TL, the first-second type clad layer CLa2, the third barrier layer B3, the second light-emitting layer 132b, the fourth barrier layer B4, the second-second type clad layer CLb2, the window layer WL, the second contact layer CTL2, and the second electrode 135. A contact hole, through which the first electrode 134 and the second electrode 135 are exposed, can be formed in the encapsulation film 136. Therefore, the plurality of bonding layers BDL and the connection electrode CE can be electrically connected to the first electrode 134 and the second electrode 135.

Next, the second planarization layer 116b can be disposed to surround the plurality of light-emitting elements ED1. The second planarization layer 116b can be disposed to surround top surfaces and side surfaces of the plurality of light-emitting elements ED1 and fix and protect the plurality of light-emitting elements ED1. For example, the second planarization layer 116b can be made of benzocyclobutene or an acrylic-based organic material, for example. However, the present disclosure is not limited thereto.

The connection electrode CE can be disposed on the second planarization layer 116b and the plurality of light-emitting elements ED1. The connection electrode CE can be in contact with the second electrode 135 disposed at the upper sides of the plurality of light-emitting elements ED1 and electrically connect the second electrodes 135 of the plurality of light-emitting elements ED1 and the power line VL. Specifically, the connection electrode CE can be electrically connected to the power line VL through contact holes formed in the passivation layer 115, the first planarization layer 116a, and the second planarization layer 116b.

The connection electrode CE can be made of an electrically conductive material, for example, a transparent conductive material such as indium tin oxide (ITO) or indium zinc oxide (IZO) or an opaque conductive material such as titanium (Ti), gold (Au), silver (Ag), copper (Cu), or an alloy thereof. However, the present disclosure is not limited thereto.

The bank BB can be disposed on the connection electrode CE. The bank BB can be disposed to be spaced apart from the light-emitting element ED1 at a predetermined interval and at least partially overlap the plurality of reflective plates RF. For example, the bank BB can cover a part of the connection electrode CE formed on the passivation layer 115, the first planarization layer 116a, and the second planarization layer 116b.

The bank BB can be made of an opaque material, for example, black resin to reduce a color mixture between the plurality of subpixels SP. However, the present disclosure is not limited thereto.

The protective layer 117 can be disposed on the connection electrode CE and the bank BB. The protective layer 117 is a layer for protecting components disposed below the protective layer 117. The protective layer 117 can be configured as a single layer or multilayer. For example, the protective layer 117 can be made of benzocyclobutene, light transmissive epoxy, a photoresist, or an acrylic-based organic material. However, the present disclosure is not limited thereto.

The optical film MF can be disposed in an entire region of an upper portion of the substrate 110 and cover an upper portion of the cover layer 160. The optical film MF can be disposed on the protective layer 117. The optical film MF can be a functional film that implements images with higher image quality while protecting the display device 1000. For example, the optical film MF can include an anti-scattering film, an anti-glare film, an anti-reflecting film, a low-reflecting film, an OLED transmittance controllable film, or a polarizing plate. However, the present disclosure is not limited thereto.

Meanwhile, a bonding part can be disposed above the substrate 110 and disposed between the protective layer 117 and the optical film MF. The bonding part can be formed on a front surface of the substrate 110 and bond the protective layer 117 and the optical film MF. The bonding part can be made of a photocurable bonding material that can be cured by light. For example, the bonding part can be made of an acrylic-based material including a photosensitive agent. However, the present disclosure is not limited thereto.

The example embodiments of the present disclosure can also be described as follows:

According to an aspect of the present disclosure, there is provided a light emitting element. The light emitting element comprises a first semiconductor layer; a first light-emitting layer disposed on the first semiconductor layer; a tunnel layer disposed on the first light-emitting layer; a second light-emitting layer disposed on the tunnel layer and configured to emit light with a wavelength different from a wavelength of light emitted from the first light-emitting layer; and a second semiconductor layer disposed on the second light-emitting layer, wherein the first light-emitting layer comprises a plurality of first sub-light-emitting layers configured to emit light with different wavelengths, and wherein the second light-emitting layer comprises a plurality of second sub-light-emitting layers configured to emit light with different wavelengths.

The plurality of first sub-light-emitting layers can comprise a first-first sub-light-emitting layer; a first-second sub-light-emitting layer disposed on the first-first sub-light-emitting layer; and a first-third sub-light-emitting layer disposed on the first-second sub-light-emitting layer, wherein the plurality of second sub-light-emitting layers can comprise a second-first sub-light-emitting layer; a second-second sub-light-emitting layer disposed on the second-first sub-light-emitting layer; and a second-third sub-light-emitting layer disposed on the second-second sub-light-emitting layer, and wherein the plurality of first sub-light-emitting layers and the plurality of second sub-light-emitting layers can be made of aluminum gallium indium phosphide (AlGaInP).

The plurality of first sub-light-emitting layers and the plurality of second sub-light-emitting layers can have different aluminum contents.

The aluminum contents of the plurality of first sub-light-emitting layers and the plurality of second sub-light-emitting layers can increase in one direction.

The first semiconductor layer can be an n-type semiconductor layer, and the second semiconductor layer can be a p-type semiconductor layer.

The aluminum contents of the plurality of first sub-light-emitting layers and the plurality of second sub-light-emitting layers can increase as the plurality of first sub-light-emitting layers and the plurality of second sub-light-emitting layers can become closer to the first semiconductor layer.

The aluminum contents of the plurality of first sub-light-emitting layers and the plurality of second sub-light-emitting layers can increase as the plurality of first sub-light-emitting layers and the plurality of second sub-light-emitting layers can become closer to the second semiconductor layer.

Emission wavelengths of the plurality of first sub-light-emitting layers and the plurality of second sub-light-emitting layers can increase in one direction.

The first semiconductor layer can be an n-type semiconductor layer, and the second semiconductor layer can be a p-type semiconductor layer.

The emission wavelengths of the plurality of first sub-light-emitting layers and the plurality of second sub-light-emitting layers can increase as the plurality of first sub-light-emitting layers and the plurality of second sub-light-emitting layers can become closer to the second semiconductor layer.

The emission wavelengths of the plurality of first sub-light-emitting layers and the plurality of second sub-light-emitting layers can increase as the plurality of first sub-light-emitting layers and the plurality of second sub-light-emitting layers can become closer to the first semiconductor layer.

The first-first sub-light-emitting layer can emit light with a wavelength of 616 nm, the first-second sub-light-emitting layer can emit light with a wavelength of 618 nm, the first-third sub-light-emitting layer can emit light with a wavelength of 620 nm, the second-first sub-light-emitting layer can emit light with a wavelength of 626 nm, the second-second sub-light-emitting layer can emit light with a wavelength of 628 nm, and the second-third sub-light-emitting layer can emit light with a wavelength of 630 nm.

The first-first sub-light-emitting layer can emit light with a wavelength of 630 nm, the first-second sub-light-emitting layer can emit light with a wavelength of 628 nm, the first-third sub-light-emitting layer can emit light with a wavelength of 626 nm, the second-first sub-light-emitting layer can emit light with a wavelength of 620 nm, the second-second sub-light-emitting layer can emit light with a wavelength of 618 nm, and the second-third sub-light-emitting layer can emit light with a wavelength of 616 nm.

The light emitting element can further comprise a clad layer disposed between the tunnel layer and the first light-emitting layer; and a window layer disposed above the second semiconductor layer.

The first semiconductor layer can be an n-type semiconductor layer made of aluminum indium phosphide (AlInP) doped with silicon (Si), and the second semiconductor layer can be a p-type semiconductor layer made of aluminum indium phosphide (AlInP) doped with magnesium (Mg).

The present disclosure being thus described, it will be obvious that the same may be varied in many ways. Such variations are not to be regarded as a departure from the spirit and scope of the present disclosure, and all such modifications as would be obvious to one skilled in the art are intended to be included within the scope of the following claims.

What is claimed is:

1. A light-emitting element comprising:
a first semiconductor layer;
a first light-emitting layer on the first semiconductor layer;
a tunnel layer on the first light-emitting layer;
a second light-emitting layer on the tunnel layer, and configured to emit light with a wavelength different from a wavelength of light emitted from the first light-emitting layer; and
a second semiconductor layer on the second light-emitting layer,
wherein the first light-emitting layer comprises a plurality of first sub-light-emitting layers configured to emit light with different wavelengths, and
wherein the second light-emitting layer comprises a plurality of second sub-light-emitting layers configured to emit light with different wavelengths.

2. The light-emitting element of claim 1, wherein the plurality of first sub-light-emitting layers comprise:
a first-first sub-light-emitting layer;
a first-second sub-light-emitting layer on the first-first sub-light-emitting layer; and
a first-third sub-light-emitting layer on the first-second sub-light-emitting layer,
wherein the plurality of second sub-light-emitting layers comprise:
a second-first sub-light-emitting layer;
a second-second sub-light-emitting layer on the second-first sub-light-emitting layer; and
a second-third sub-light-emitting layer on the second-second sub-light-emitting layer, and
wherein the plurality of first sub-light-emitting layers and the plurality of second sub-light-emitting layers include aluminum gallium indium phosphide (AlGaInP).

3. The light-emitting element of claim 2, wherein the plurality of first sub-light-emitting layers and the plurality of second sub-light-emitting layers have different aluminum contents.

4. The light-emitting element of claim 2, wherein aluminum contents of the plurality of first sub-light-emitting layers and the plurality of second sub-light-emitting layers increase in one direction.

5. The light-emitting element of claim 4, wherein the first semiconductor layer is an n-type semiconductor layer, and the second semiconductor layer is a p-type semiconductor layer.

6. The light-emitting element of claim 5, wherein the aluminum contents of the plurality of first sub-light-emitting layers and the plurality of second sub-light-emitting layers increase as the plurality of first sub-light-emitting layers and the plurality of second sub-light-emitting layers become closer to the first semiconductor layer.

7. The light-emitting element of claim 5, wherein the aluminum contents of the plurality of first sub-light-emitting layers and the plurality of second sub-light-emitting layers increase as the plurality of first sub-light-emitting layers and the plurality of second sub-light-emitting layers become closer to the second semiconductor layer.

8. The light-emitting element of claim 2, wherein aluminum content of the first-first sub-light-emitting layer is 0.18% to 0.19%, aluminum content of the first-second sub-light-emitting layer is 0.17% to 0.18%, aluminum content of the first-third sub-light-emitting layer is 0.16% to 0.17%, aluminum content of the second-first sub-light-emitting layer is 0.13% to 0.14%, aluminum content of the second-second sub-light-emitting layer is 0.12% to 0.13%, and aluminum content of the second-third sub-light-emitting layer is 0.11% to 0.12%.

9. The light-emitting element of claim 2, wherein aluminum content of the first-first sub-light-emitting layer is 0.11% to 0.12%, aluminum content of the first-second sub-light-emitting layer is 0.12% to 0.13%, aluminum content of the first-third sub-light-emitting layer is 0.13% to 0.14%, aluminum content of the second-first sub-light-emitting layer is 0.16% to 0.17%, aluminum content of the second-second sub-light-emitting layer is 0.17% to 0.18%, and aluminum content of the second-third sub-light-emitting layer is 0.18% to 0.19%.

10. The light-emitting element of claim 2, wherein emission wavelengths of the plurality of first sub-light-emitting layers and the plurality of second sub-light-emitting layers increase in one direction.

11. The light-emitting element of claim 10, wherein the first semiconductor layer is an n-type semiconductor layer, and the second semiconductor layer is a p-type semiconductor layer.

12. The light-emitting element of claim 11, wherein the emission wavelengths of the plurality of first sub-light-emitting layers and the plurality of second sub-light-emitting layers increase as the plurality of first sub-light-emitting layers and the plurality of second sub-light-emitting layers become closer to the second semiconductor layer.

13. The light-emitting element of claim 11, wherein the emission wavelengths of the plurality of first sub-light-emitting layers and the plurality of second sub-light-emitting layers increase as the plurality of first sub-light-emitting layers and the plurality of second sub-light-emitting layers become closer to the first semiconductor layer.

14. The light-emitting element of claim 2, wherein the first-first sub-light-emitting layer emits light with a wavelength of about 616 nm,
the first-second sub-light-emitting layer emits light with a wavelength of about 618 nm,
the first-third sub-light-emitting layer emits light with a wavelength of about 620 nm,
the second-first sub-light-emitting layer emits light with a wavelength of about 626 nm,
the second-second sub-light-emitting layer emits light with a wavelength of about 628 nm, and
the second-third sub-light-emitting layer emits light with a wavelength of 630 nm.

15. The light-emitting element of claim 2, wherein the first-first sub-light-emitting layer emits light with a wavelength of about 630 nm,
the first-second sub-light-emitting layer emits light with a wavelength of about 628 nm,
the first-third sub-light-emitting layer emits light with a wavelength of about 626 nm,
the second-first sub-light-emitting layer emits light with a wavelength of about 620 nm,
the second-second sub-light-emitting layer emits light with a wavelength of about 618 nm, and
the second-third sub-light-emitting layer emits light with a wavelength of about 616 nm.

16. The light-emitting element of claim 1, further comprising:
a clad layer disposed between the tunnel layer and the first light-emitting layer; and
a window layer disposed above the second semiconductor layer.

17. The light-emitting element of claim 1, wherein the first semiconductor layer is an n-type semiconductor layer made of aluminum indium phosphide (AlInP) doped with silicon (Si), and
the second semiconductor layer is a p-type semiconductor layer made of aluminum indium phosphide (AlInP) doped with magnesium (Mg).

18. The light-emitting element of claim 1, wherein the plurality of first sub-light-emitting layers and the plurality of second sub-light-emitting layers are configured to emit red light with different wavelengths.

19. The light-emitting element of claim 18, wherein the plurality of first sub-light-emitting layers and the plurality of second sub-light-emitting layers configured to emit red light with different wavelengths have a smaller band gap than light-emitting layers of light-emitting elements configured to emit light with other colors.

20. A display device comprising:
a display panel including a plurality of sub-pixels configured to display images,
wherein each of the plurality of sub-pixels includes the light-emitting element of claim 1; and
a gate drive part and a data drive part configured to drive the display panel.
